(19) United States
(12) Patent Application Publication
(10) Pub. No.: US 2024/0076435 A1
(43) Pub. Date: Mar. 7, 2024

(54) THERMALLY CONDUCTIVE POLYMER

(71) Applicant: Sumitomo Chemical Co., Ltd, Tokyo (JP)

(72) Inventors: Simon Mark King, Godmanchester (GB); Przemyslaw Gawel, Warsaw (PL); Thomas Fletcher, Godmanchester (GB)

(21) Appl. No.: 18/269,403

(22) PCT Filed: Dec. 22, 2021
(86) PCT No.: PCT/EP2021/087368

§ 371 Date: Jun. 23, 2023

(30) Foreign Application Priority Data
Dec. 23, 2020 (GB) 2020482.2
Aug. 6, 2021 (GB) 2111395.6
Aug. 27, 2021 (GB) 2112301.3

(51) Int. Cl. C08G 12/08

(52) U.S. Cl. CPC C08G 12/08

(57) ABSTRACT

A polymer comprising a repeating structure of formula (I) wherein Ar in each occurrence is an arylene or heteroarylene group; p is at least 2; one of Y¹ and Y2 is CR¹ wherein R¹ is H or a substituent; and the other of Y¹ and Y² is N. The polymer may be formed by reaction of monomers containing reactive groups which react to form an imine. The polymer may be used as a thermally conductive polymer, e.g. a thermally conductive layer of an electronic device.

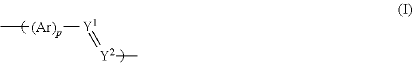

### BACKGROUND

Thermally conductive materials are used in a wide variety of applications including in underfill for flip-chips to reduce thermally induced stresses following application of a flip chip.

Mary Liu and Wusheng Yin, “A novel high thermal conductive underfill for flip chip application” http://yincae.com/assets/wp-1000-03_2013.pdf discloses an underfill containing diamond powder.

Islam et al, “Enhanced Thermal Conductivity of Liquid Crystalline Epoxy Resin using Controlled Linear Polymerization”, ACS Macro Lett. 2018, 7, 10, 1180-1185 discloses liquid crystalline epoxy resin with a 2-D boron nitride filler.

WO 2019/143823 discloses thermally conductive quinoid-type conjugated polymer thin films fabricated by oxidative chemical vapour deposition.

Huang et al, “Thermal conductivity of polymers and polymer nanocomposites”, Materials Science and Engineering: R: Reports, Vol. 132, October 2018, p. 1-22 describes thermal transport mechanisms in polymers.

Suematsu et al, “Polyimine, a C═N Double Bond Containing Polymers: Synthesis and Properties” Polymer Journal, Vol. 15, No. I, pp 71-79 (1983) discloses a polyimine of formula:

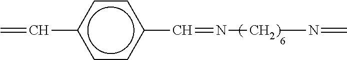

### SUMMARY

The present disclosure provides a polymer comprising a repeating structure of formula (I):

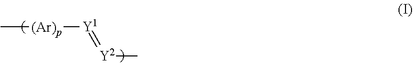

wherein Ar in each occurrence is an arylene or heteroarylene group; p is at least 2; one of Y¹ and Y² is CR¹ wherein R¹ is H or a substituent; and the other of Y¹ and Y² is N.

Optionally, p is 2-5.

Optionally, each Ar of (Ar)p is independently selected from para-phenylene, thiophene, furan, and benzobisoxazole, each of which may independently be unsubstituted or substituted with one or more substituents. Preferably each Ar is phenylene.

Optionally, each Ar of (Ar)p is the same.

Optionally, one or more Ar groups of (Ar)p are substituted with one or more substituents selected from substituents R² wherein R² in each occurrence is independently selected from:
F;
CN;
NO₂;
branched, linear or cyclic C₁₋₄₀ alkyl, preferably a C₁₋₂₀ alkyl, wherein one or more non-adjacent C-atoms may be replaced with O, S, NR⁵, SiR⁶₂, C═O or COO wherein R⁵ in each occurrence is H or a substituent and R⁶ in each occurrence is independently a substituent; or
an aryl or heteroaryl group Ar⁵ which is unsubstituted or substituted with one or more substituents. Optionally, at least one R² is a C₁₋₂₀ alkyl or C₁₋₁₉ alkoxy group.

Optionally, R¹ is H or a C₁₋₂₀ hydrocarbyl group.

In a preferred embodiment, the polymer is not fluorinated.

Optionally, a divalent linker group L disposed in the polymer backbone, wherein L is selected from O, S, NR⁵ or a C₁₋₁₂ alkylene group wherein one or more non-adjacent C atoms may be replaced with O, S, NR⁵, SiR⁶₂, CO or COO wherein R⁵ in each occurrence is H or a substituent and R⁶ in each occurrence is independently a substituent.

Optionally, the repeating structure of formula (I) is comprised in a repeating group of formula (II), (III) or (IV).

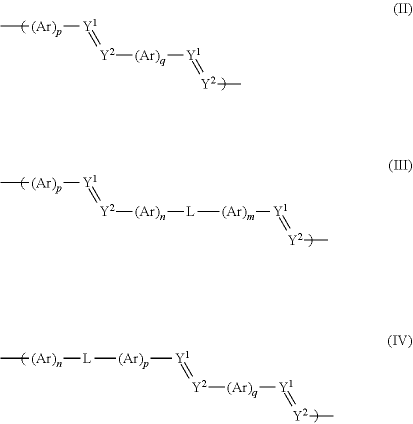

wherein:
q is at least 1;
n is 0 or a positive integer;
m is 0 or a positive integer; and
L is as described above.

The present disclosure provides a film comprising a polymer as described herein.

The present disclosure provides a method of forming a film as described herein comprising deposition of one or more monomers for forming the polymer onto a surface and polymerising the one or more monomers.

Optionally, the one or more monomers are deposited from a solution.

Optionally, the surface is a surface of a functional layer of an electronic device.

The present disclosure provides apparatus comprising a heat-generating device, a heat transfer device configured to transfer heat away from the heat-generating device and a film according to claim 10 disposed between the heat-generating device and the heat transfer device.

The present disclosure provides an electronic device comprising a film as described herein disposed on a functional layer thereof.

Optionally, the film is disposed in a region between the surface of the functional layer and a first surface of a first chip electrically connected to the functional layer.

Optionally, the functional layer is a printed circuit board; an interposer; or a second chip.

Optionally, the electronic device comprises a 3D chip stack.

The present disclosure provides a heat sink comprising a first surface having fins extending therefrom and an opposing second surface having a film as described herein disposed thereon.

The present disclosure provides a method of forming a polymer as described herein comprising polymerisation of a monomer or monomers having reactive groups which react to form Y¹═Y².

Optionally, the method comprises polymerisation of a first monomer selected from formulae (M1-A) and (M1-B) and a second monomer selected from formulae (M2-A) and (M2-B):

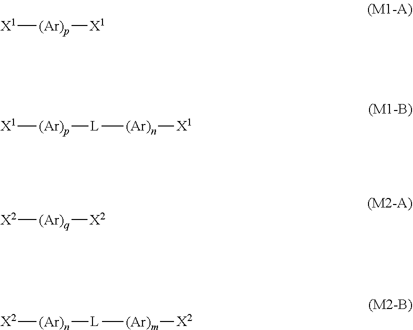

wherein one of X¹ and X² is a group of formula —C(═O)R¹ and the other of X¹ and X² is NH₂; and q, n and m and L are as described above.

Optionally, the method comprises polymerisation of a monomer of formula (M3):

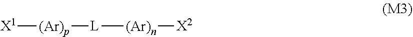

wherein one of X¹ and X² is a group of formula —C(═O)R¹ and the other of X¹ and X² is NH₂; n is 0 or a positive integer; and L is as described above.

The present disclosure provides a formulation comprising one or more monomers for forming the polymer as described herein and a solvent wherein the one or more monomers are dissolved in the solvent.

### DESCRIPTION OF DRAWINGS

FIG. 1 schematically illustrates an electronic device according to some embodiments comprising a flip-chip electrically connected to a substrate;

FIG. 2A schematically illustrates a method according to some embodiments of forming the electronic device of FIG. 1 in which an underfill layer is formed between the substrate and the flip-chip;

FIG. 2B schematically illustrates a method according to some embodiments of forming the electronic device of FIG. 1 in which a non-conducting film is applied to the flip chip prior to connection to the substrate;

FIG. 3 schematically illustrates a 3D chip stack according to some embodiments;

FIG. 4 schematically illustrates a substrate for measurement of thermal conductivity of a film; and

FIGS. 5A and 5B schematically illustrate apparatus for measurement of thermal conductivity including the substrate of FIG. 4.

The drawings are not drawn to scale and have various viewpoints and perspectives. The drawings are some implementations and examples. Additionally, some components and/or operations may be separated into different blocks or combined into a single block for the purposes of discussion of some of the embodiments of the disclosed technology. Moreover, while the technology is amenable to various modifications and alternative forms, specific embodiments have been shown by way of example in the drawings and are described in detail below. The intention, however, is not to limit the technology to the particular implementations described. On the contrary, the technology is intended to cover all modifications, equivalents, and alternatives falling within the scope of the technology as defined by the appended claims.

### DETAILED DESCRIPTION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list. References to a layer “over” another layer when used in this application means that the layers may be in direct contact or one or more intervening layers are may be present. References to a layer “on” another layer when used in this application means that the layers are in direct contact.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms.

In the following description, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

The present inventors have found that a high thermal conductivity may be provided by a film comprising or consisting of a polymer comprising a repeating structure of formula (I):

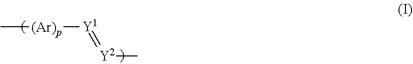

wherein Ar in each occurrence is an arylene or heteroarylene group; p is at least 2; one of Y¹ and Y² is CR¹ wherein R¹ is H or a substituent; and the other of Y¹ and Y² is N.

The extended rigid-rod type structure of formula (I) may enhance thermal conductivity of the polymer as compared to the case where p=1.

Optionally, thermal conductivity of polymers as described herein is at least 0.15 Wm⁻¹K⁻¹, optionally at least 0.2 or 0.3 Wm⁻¹K⁻¹.

p is preferably 2-5.

Ar in each occurrence in (Ar)p may be the same or different, preferably the same.

Exemplary Ar groups include, without limitation, para-phenylene, thiophene, furan, and benzobisoxazole, each of which may independently be unsubstituted or substituted with one or more substituents. Para-phenylene is preferred.

Exemplary groups (Ar)p include, without limitation, groups of formulae (Va) and (Vb):

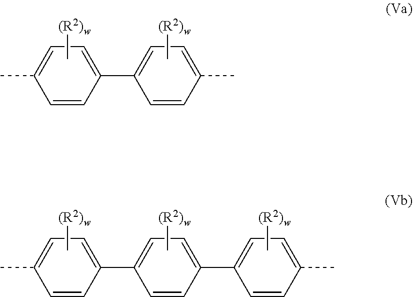

wherein R² independently in each occurrence is a substituent and w in each occurrence is independently 0 or a positive integer.

A preferred group (Ar)p has formula (Vc-1):

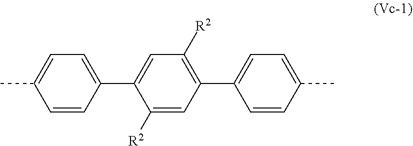

R¹ is preferably H or a C₁₋₂₀ hydrocarbyl group, more preferably H.

A C₁₋₂₀ hydrocarbyl group as described anywhere herein is preferably selected from C₁₋₂₀ alkyl; unsubstituted phenyl; and phenyl substituted with one or more C₁₋₁₂ alkyl groups.

Optionally, one or more Ar groups of (Ar)ₚ are substituted with one or more substituents R². Preferably, R² in each occurrence is independently selected from:
F;
CN;
NO₂;
branched, linear or cyclic C₁₋₄₀ alkyl, preferably C₁₋₂₀ alkyl, wherein one or more non-adjacent C-atoms may be replaced with O, S, NR⁵, SiR⁶₂, C═O or COO; wherein R⁵ in each occurrence is H or a substituent, preferably H or a C₁₋₂₀ hydrocarbyl group and R⁶ in each occurrence is independently a substituent, optionally a C₁₋₂₀ hydrocarbyl group; or an aryl or heteroaryl group Ar⁵ which is unsubstituted or substituted with one or more substituents, optionally phenyl which is unsubstituted or substituted with one or more substituents selected from F, CN, NO₂ and branched, linear or cyclic C₁₋₂₀ alkyl wherein one or more non-adjacent C-atoms may be replaced with O, S, NR⁵, SiR⁶₂, C═O or COO.

Preferably, at least one substituent R², optionally each substituent R², is C₁₋₂₀ alkyl, C₁₋₂₀ alkoxy, or a group of formula -(Ak¹)_{y}-(OCH₂CH₂)_{z}-Ak² wherein Ak¹ is a C₁₋₄ alkylene group; y is 0 or 1; z is 1-15; and Ak² is a C₁₋₄ alkyl group. More preferably R² is a C₁₋₁₂ alkyl or C₁₋₁₂ alkoxy. C₁₋₁₂ alkoxy is particularly preferred.

The polymer may comprise a divalent linker group L disposed in the polymer backbone, wherein L is selected from O, S, NR⁵ or a C₁₋₁₂ alkylene group wherein one or more non-adjacent C atoms of a C₂₋₁₂ alkylene group may be replaced with O, S, NR⁵, SiR⁶₂, CO or COO.

In some embodiments, the divalent linker group L is disposed between and linked directly to two Ar groups.

In some embodiments, the divalent linker group L is disposed between and linked directly to an Ar group and an imine (—C(R¹)═N—) group.

In some embodiments, the divalent linker group L is disposed between and linked directly to two imine (—C(R¹)═N—) groups.

The polymer may be formed by polymerising a monomer or monomers having reactive groups which react to form an imine. The repeating structure of formula (I) may be part of a larger repeat unit of the polymer formed by polymerising the monomer or monomers. Exemplary repeat units include, without limitation, formulae (II)-(IV):

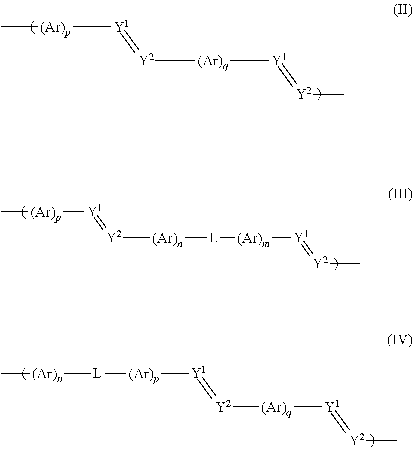

wherein Ar, p, Y¹, Y² and L are as described above;
q is at least 1, preferably 1-5, more preferably 1-3;
n is 0 or a positive integer, preferably 0 or 1-5, more preferably 0, 1, 2 or 3; and
m is 0 or a positive integer, preferably 0 or 1-5, more preferably 0, 1, 2 or 3.

If q is greater than 1 then each Ar of (Ar)q, may be the same or different, preferably the same.

If n is greater than 1 then each Ar of (Ar)n, may be the same or different, preferably the same.

If m is greater than 1 then each Ar of (Ar)m, may be the same or different, preferably the same.

Preferred Ar groups of (Ar)q, (Ar)m and (Ar)m are as described with reference to (Ar)p.

The repeat units of the polymer may be the same or different. In some embodiments, the polymer contains a mixture of different repeat units of formulae (II)-(IV). The polymer may contain one or more of: different repeat units of formula (II); different repeat units of formula (III); different repeat units of formula (IV); and a repeat unit selected from one of formulae (II)-(IV) and at least one other repeat unit selected from another of formulae (II)-(IV). In a preferred embodiment, the polymer contains a repeat unit without a divalent linker group L and a repeat unit with a divalent linker group L, for example a repeat unit of formula (II) and a repeat unit of formula (III).

In the case where n and m are each 0, the repeat unit of formula (III) has formula (IIIa):

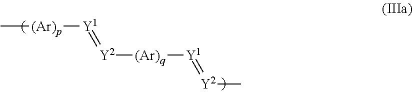

The polymers may be substituted with groups for bonding together of polymer chains, e.g. hydrogen bonding or covalent bonding, to enhance long-range ordering of the polymers.

Polymers as described herein are preferably at least partially crystalline.

Polymers as described herein may undergo pi-pi stacking when deposited as a film.

The polystyrene-equivalent number-average molecular weight (Mn) measured by gel permeation chromatography of the polymers described herein may be in the range of about 1×10³ to 1×10⁸, and preferably 1×10⁴ to 5×10⁶. The polystyrene-equivalent weight-average molecular weight (Mw) of the polymers described herein may be 1×10³ to 1×10⁸, and preferably 1×10⁴ to 1×10⁷.

Polymerisation

The polymer may be formed by polymerising a monomer or monomers having reactive groups which react to form an imine.

In some embodiments, polymers as described herein are formed by polymerisation of a first monomer comprising a group of formula (I) and two reactive groups X¹ with a second monomer comprising two reactive groups X² wherein one of X1 and X2 is a group of formula —C(═O)R¹ and the other of X¹ and X² is NH₂.

Optionally according to these embodiments, the first monomer is selected from formulae (M1-A)-(M1-B) and and the second monomer is selected from formulae (M2-A) and (M2-B):

X¹—(Ar)ₚ—X¹ (M1-A)

X¹—(Ar)ₚ-L-(Ar)ₙ—X¹ (M1-B)

X²—(Ar)_{q}—X² (M2-A)

X₂—(Ar)ₙ-L-(Ar)ₘ—X² (M2-B)

In some embodiments, only one monomer substituted with X¹ groups and only one monomer substituted with X² groups are reacted. It will be understood that the polymer formed from these monomers will contain only one repeat unit structure.

In some embodiments, two or more different monomers substituted with X¹ groups and/or two or more different monomers substituted with X² groups are reacted. It will be understood that the polymer formed from these monomers will contain two or more different repeat unit structures.

In some embodiments, a polymer comprising a repeating structure of formula (I) may be formed by polymerisation of a monomer of formula (M3):

X¹—(Ar)ₚ-L-(Ar)ₙ—X² (M3)

In some embodiments, only one monomer of formula (M3) is reacted. It will be understood that the polymer formed from this monomer will contain only one repeat unit structure.

In some embodiments, two or more different monomers of formula (M3) are reacted. It will be understood that the polymer formed from these monomers will contain two or more different repeat unit structures.

The reaction between X¹ and X² may be catalysed by a Lewis acid. The Lewis acid may or may not be a Bronsted-Lowry acid.

The present inventors have surprisingly found that thermal conductivity of a polymer as described herein may be increased by polymerisation of monomers in the presence of a Lewis acid catalyst as compared to formation of the polymer without a catalyst.

Exemplary catalysts include, without limitation, sulfonic acids and salts thereof, for example p-toluene sulfonic acid; triflic acid; and salts thereof. An exemplary triflic acid salt is scandium triflate, Sc(Trf)₃. The catalyst may be provided in an amount of 0.01-0.3 molar equivalents of the total number of moles of the monomer or monomers.

Film Formation

Formation of a film comprising a polymer as described herein may comprise formation of a precursor film comprising the monomer or monomers for forming the polymer followed by polymerisation of the monomers, referred to hereinafter as in situ polymerisation. The precursor film may consist of the monomer or monomers for forming the polymer or the precursor film may be a composition comprising one or more further materials, e.g. a Lewis acid catalyst as described herein.

In some preferred embodiments of in situ polymerisation, the precursor film formation comprises deposition of a monomer formulation comprising the monomer or monomers dissolved in one or more solvents. According to these embodiments, in-situ polymerisation preferably takes place in solution. The monomer formulation may or may not comprise a catalyst.

Solvents may be selected according to their ability to dissolve the, or each, monomer. Exemplary solvents include, without limitation, benzene or naphthalene substituted with one or more substituents, optionally one or more substituents selected from C₁₋₁₂alkyl, C₁₋₁₂alkoxy, F and Cl; ethers; esters; halogenated alkanes; ketones; sulfoxides; and mixtures thereof. Exemplary solvents include, without limitation, xylenes, 1,2,4-trimethylbenzene, mesitylene, 1-methylnaphthalene, 1-chloronaphthalene, diiodomethane, anisole, N-methylpyrrolidone, 1,2-dimethoxybenzene, dimethylsulfoxide 1,3-dimethyl-2-imidazolidinone and cyclopentanone.

The concentration of each monomer dissolved in the monomer formulation is preferably in the range of about 1-50 mg/ml, more preferably about 10-40 mg/ml. The monomer formulation may be heated to achieve dissolution of the monomer or monomers.

The polymer precursor film may be heated before and/or after polymerisation. In some embodiments, the polymer precursor film may be dried at a temperature of up to about 100° C., optionally 50-70° C. The dried film may be heated at a temperature above 100° C., optionally in the range of 100-200° C. The temperature applied before, during or after drying may be below a melting point of the monomer or, if more than one monomer is present, to below the melting point of the monomer having the lowest melting point. The temperature applied before, during or after drying may be at or above a melting point of the monomer or, if more than one monomer is present, at or above the melting point of the monomer having the lowest melting point.

In some preferred embodiments of in-situ polymerisation, a monomer formulation comprising monomer particles mixed with a liquid is deposited on a surface to form a polymer precursor film and the film is heated to at least the melting point of the monomer or, if more than one monomer is present, to at least the melting point of the monomer having the lowest melting point. Optionally, the polymer precursor film is heated at below the lowest monomer melting point to drive off the liquid before the heating temperature is increased to at least this melting point. It will be appreciated that the amount and/or nature of the liquid is such that the monomer particles are not dissolved in the liquid. Preferably, the or each monomer is sparingly soluble or insoluble in the liquid. The liquid may be a single liquid material or a mixture of two or more liquid materials, for example one or more liquids selected from water and C₁₋₆ alcohols. The monomer formulation according to these embodiments may be, for example, a suspension or a paste and a suitable deposition method may be selected accordingly.

Monomer formulations as described anywhere herein may be deposited by any suitable solution deposition technique including, without limitation, spin-coating, dip-coating, drop-casting, spray coating and blade coating.

The film may consist of the polymer or may contain one or more further materials, optionally one or more amorphous polymers, e.g. polystyrene, polyethylene or polypropylene; and/or one or more thermally conductive materials, for example boron nitride.

In some embodiments, the film comprises thermally conductive particles dispersed therein.

In some embodiments, the film does not comprise any thermally conductive particles, such as boron nitride.

Optionally, a film comprising or consisting of a polymer as described herein has a thickness in the range of 1-100 microns, preferably 10-100 microns.

Applications

A film comprising a polymer as described herein may be used in any known application of a thermally conductive film. The film as described herein may be disposed between a surface of a heat-generating device and a heat transfer device configured to transfer heat away from the heat-generating device, such as in any known thermal interface management application.

It will be understood that in this arrangement the film is configured to transfer heat from the heat-generating device to the heat transfer device. The film preferably has a first surface in direct contact with a surface of the heat-generating device and/or a second surface opposing the first surface in direct contact with a surface of the heat transfer device.

The heat-generating device may be an electronic device.

Any passive or active heat transfer device known to the skilled person may be used including, without limitation, a heat sink having a surface in contact with the film and an opposing surface comprising one or more heat-dissipating features, for example fins or a pipe or channel configured to transfer heat to a fluid flowing through the pipe or channel. The fluid may or may not undergo a phase change upon absorption of heat.

Preferably, the film is a thermally conductive layer of an electronic device.

Heat may be transferred from a surface by bringing a layer comprising a thermally conductive film as described herein adjacent to the surface. The thermally conductive film may be in direct contact with the surface or it may be spaced apart from the surface by one or more thermally conductive layers.

A film as described herein may be disposed on a surface of a heat sink opposing a surface of the heat sink having fins extending therefrom. In use, the film may be disposed between the heat sink and an electrical component.

A film as described herein may be a heat spreader layer disposed on a surface of a printed circuit board, for example a PCB for use in LED arrays.

A film as described herein may be used as an electrically non-conductive film, e.g. an underfill, for a flip chip including but not limited to 3D stacked multi-chips.

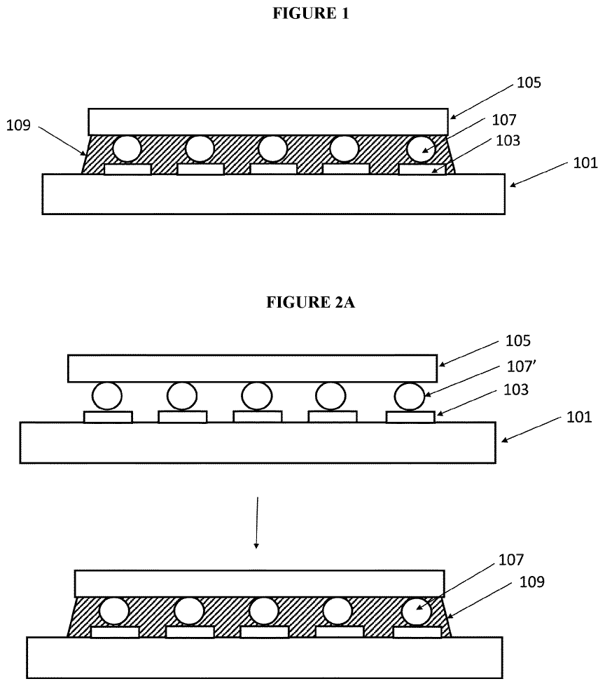

FIG. 1 illustrates an electronic device comprising a chip 105; a substrate 101, e.g. a printed circuit board; and electrically conductive interconnects 107 between electrically conductive pads 103 on the surface of the substrate 101 and the chip 105. Underfill 109 comprising or consisting of a polymer as described herein fills the region between the chip 105 and substrate 101. Optionally, the polymer is crosslinked.

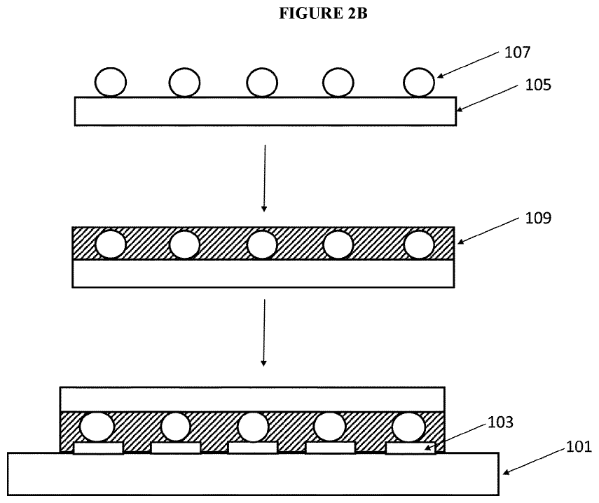

With reference to FIG. 2A, in some embodiments formation of an electronic device comprises bringing electrically conductive bumps 107′, e.g. solder bumps, into contact with electrically conductive pads 103 disposed on a substrate 101, e.g. a printed circuit board to form interconnects 107 from electrically conductive bumps 107′. Formation of underfill 109 comprising a polymer as described herein comprises application of a formulation comprising the monomer or monomers into the overlap region between the chip 105 and the substrate 101. Optionally, the polymer is crosslinked following application of the formulation and reaction of the monomer or monomers, e.g. by heat and/or UV treatment.

With reference to FIG. 2B, in some embodiments a polymer precursor film is formed over a surface of the chip 105 carrying electrically conductive bumps 107′. FIG. 4B illustrates complete coverage of the conductive bumps 107′ however it will be understood that the conductive bumps 107′ may be partially covered such that a part of the conductive bumps 107′ protrude from a surface of the film 109. The conductive bumps 107′ are then brought into contact with conductive pads 103 disposed on a substrate 101, e.g. a printed circuit board, to form electrically conductive interconnects between the substrate and the chip. Formation of the electrically conductive interconnects may comprise application of heat and/or pressure.

If the polymer of film 109 is crosslinked then crosslinking may take place before, during or after the conductive bumps 107′ are brought into contact with the conductive pads 103.

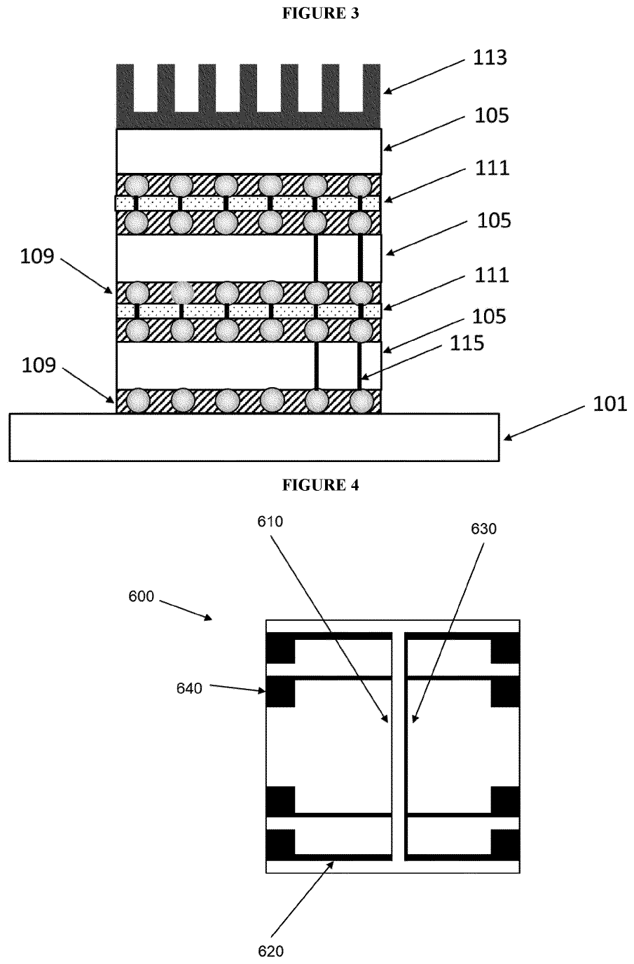

Two or more chips may be connected with a film comprising a polymer as described herein disposed between chips. FIG. 3 illustrates a 3D stack of chips 105 according to some embodiments, wherein the chips 105 are interposed by an interposer 111 and a non-electrically conductive film 109 disposed between adjacent interposer and chip surfaces and between the substrate 101, e.g. a printed circuit board, and a first chip of the 3D stack. At least one non-electrically conductive film 109 comprises a polymer as described herein. Through-vias 115 are formed through the chips 105 and the interposers. The 3D stack may comprise a heat sink 113 disposed on a surface thereof.

In some embodiments, a film comprising or consisting of a polymer as described herein may be disposed between an electronic device and a heat sink.

### EXAMPLES

In-Situ Solution Polymerisation

Polymers were formed by depositing a solution of a diamine monomer and a dialdehyde monomers as set out in Table 1 and reacting the monomers. Some monomers were reacted in the presence of a Lewis acid catalyst. Some polymers were annealed following polymerisation.

Monomers were dissolved in the solvent at the same desired concentration (w/v) e.g 10 mg/ml, optionally applying heat up to 80° C. to aid dissolution. The monomer inks were mixed by volume to produce an equimolar mixture of the monomers. A catalyst may be added by the same method of pre-dissolving and mixing by volume to achieve the desired molar ratio of catalyst to monomer. For illustration, a 1:1:0.15 molar mixture of monomers A2 (Mw 108.144) and B2 (Mw 454.65) illustrated below plus scandium triflate catalyst (Mw 492.16) at 10 mg/ml is prepared by first preparing bulk solutions of each component at 10 mg/ml, then mixing them in a 0.18:0.758:0.062 volume ratio.

After mixing the ink is promptly dropcast onto a substrate described below for thermal conductivity measurement. A gasket prepared from 0.5 mm thick fluorosilicone rubber sheet (Silex Silicones Ltd) and applied to the substrate is used to contain the ink within a prescribed area (18×l0 mm rectangle) for the dropcasting procedure. The wet film is dried by evaporation on a hotplate which may be at room temperature or any temperature below the solvent boiling point; for the examples in the table the drying temperature was consistently 50° C. After drying the gasket is removed and the film is optionally annealed at 170° C. for 2 hours.

Results are set out in Table 1.

TABLE 1

| | | | | | Annealing | Thermal |
|---|---|---|---|---|---|---|
| | Diamine | Dialdehyde | | | temperature | Conductivity |
| Polymer | monomer | monomer | Solvent | Catalyst | (° C.) | (WmK⁻¹) |
| Comparative Polymer 1 | | | Epoxy | — | — | 0.14 |
| Polymer Example 1A | A1 | B1 | DMSO | — | — | 0.11 |
| Polymer Example 1B | A1 | B1 | DMSO | ScTrf | — | 0.17 |
| Polymer Example 1C | A1 | B1 | DMSO | PTSA | — | 0.17 |
| Polymer Example 1D | A1 | B1 | DMSO | PTSA | 170 | 0.17 |
| Polymer Example 2 | A1 | B2 | DMSO | ScTrf | — | 0.14 |
| Polymer Example 3A | A2 | B2 | Cyclopentanone | ScTrf | — | 0.21 |
| Polymer Example 3B | A2 | B2 | Cyclopentanone | ScTrf | 170 | 0.32 |
| Polymer Example 3C | A2 | B2 | Cyclopentanone | PTSA | | 0.18 |
| Polymer Example 3D | A2 | B2 | Cyclopentanone | PTSA | 170 | 0.31 |
| Polymer Example 4A | A3 | B2 | Anisole | ScTrf | 170 | 0.32 |
| Polymer Example 5A | A3 | B3 | o-xylene | ScTrf | — | 0.22 |
| Polymer Example 5B | A3 | B3 | o-xylene | — | — | 0.50 |

PTSA = para-toluenesulfonic acid 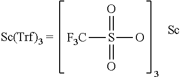
A1 = terphenyl diamine 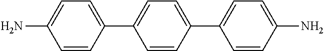 [SMILES: Nc1ccc(-c2ccc(-c3ccc(N)cc3)cc2)cc1]
A2 = phenyl diamine 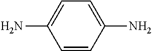
A3 = ethylene dianiline 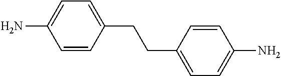 [SMILES: Nc1ccc(CCc2ccc(N)cc2)cc1]
B1 = terphenyl dialdehyde 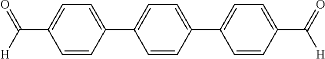 [SMILES: O=Cc1ccc(-c2ccc(-c3ccc(C=O)cc3)cc2)cc1]
B2 = dihexyl terphenyl dialdehyde 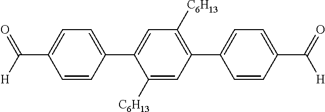
B3 = dihexyloxy terphenyl dialdehyde 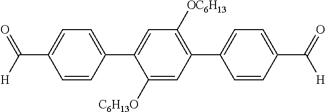
B4 = dibutyloxy terphenyl dialdehyde

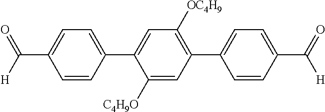

Comparative Polymer 1 was formed from a 1:1 v/v mixture of Epikote Resin 862 and Epikure Curing Agent 866 (both Hexion) plus 0.1% tetrabutylphosphonium bromide (purchased from Sigma).

Thermal conductivity was measured as described below. It was found that monomers without alkyl substituents or an alkylene linker to enhance solubility formed poorer films, although the thermal conductivity of these films could be enhanced by annealing and/or use of a catalyst.

Thermal Conductivity Measurement

A sensor substrate 600 (ca. 25 mm×25 mm) illustrated in FIG. 4 was used for measurement of thermal conductivity as described herein. The substrate has a polyethylene naphthalate (PEN) film (Dupont Teonex Q83, 25 μm) with a 200 nm thick heating structure consisting of a micron wide heater line 610, 500 micron wide busbars 620 for application of a current and contact pads 640. A sensing structure mirrors the heating structure except that the heater line is replaced with a 200 micron wide sensor line 630.

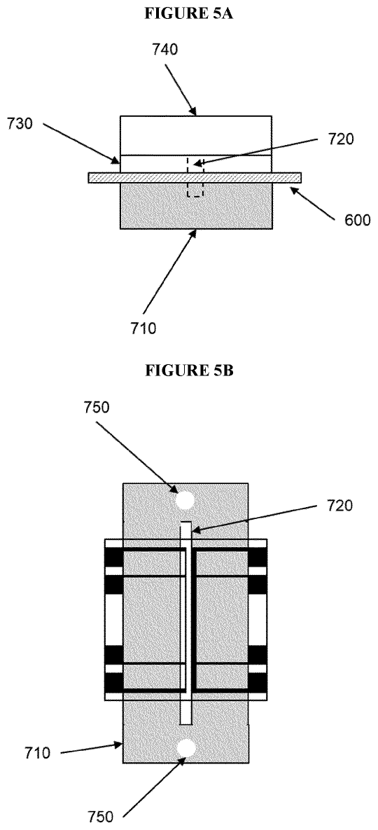

With reference to FIGS. 5A and 5B, the sensor substrate 600 carrying the film to be measured is placed on a temperature controlled aluminium block, regulated via a PID system such that the temperature may be controlled by software. The aluminium block has a long notch 720 of 1 mm width and ˜1 mm depth cut into it. The sensor substrate 600 is placed over the notch such that the central heater line 610 is aligned with the centre of the notch 720, and the sensor line 630 is aligned with the edge of the notch. A PMMA sheet 730 (2 mm thickness) with a notch cut-through matching that of the aluminium block 710 is placed over the top and an addition piece of plain PMMA sheet 740 (4 mm thickness) is placed on top to enclose the device. The entire assembly is clamped using bolts and nuts at positions 750. The heater line is connected to a sourcemeter unit (Keithley 2400) using a 4-wire measurement set up. The sensor line is connected to a multimeter unit (Keithley 2000) using a 4 wire set up.

The temperature of the assembly is first stabilised at a predetermined temperature. The resistance of the heater line and the temperature sensor is then measured. To measure the resistance of the heater line without causing undue heating a low current is sourced and voltage measured in short pulses, with time allowed between pulses for heat to be dissipated. A constant DC current is then passed along the heater line to cause resistive heating. The arrangement of the substrate in the assembly causes heat to flow through the substrate and film to the aluminium block which acts as a heat sink, setting up an approximate one-dimensional steady state heat flux. The power dissipated in the heater line, and the resistance of the heater line and temperature sensor is additionally measured in this state. This process is repeated for increasing sourced current, and the complete process repeated at the next temperature setpoint.

The resistances of the heater line and sensor lines under the condition of no heat flux at different temperature setpoints are used as calibration data in a straight-line fit of resistance and temperature, allowing the temperature of the resistive elements to be determined under the condition of steady state heat flux. As such the temperature gradient, ΔT, between the heater line and temperature sensor (aligned with the heatsink) can then be calculated. The power dissipated in the heater line is assumed to be completely converted to heat energy Q. A straight line fit is then made between dT and Q with additional parameters for the length of the heater line over which power is measured (L, 14.4 mm), the distance between the voltage sense points) and the gap width (2w, 1 mm). This provides a measure of the conductance C of the device under test and is affected by losses pertaining to conductive heat transfer in the substrate and convective and radiative heat transfer to the environment (h).

To calculate a thermal conductivity κ, the same measurement process is carried out on substrates without any test film (substrate only). We assume the losses will be approximately the same when measuring a coated vs uncoated substrate. We subtract the conductance of the substrate (C_{S}) from the device measurement (C_{F+S}) to adjust for these losses. The thermal conductivity (k_{F}) is then calculated by dividing the resulting film only conductance by the film thickness (d_{F}). The film thickness is determined using a digital micrometer by measuring the total thickness and subtracting the substrate thickness.

$$C = \frac{Q w}{2 L Δ T} = κ d + 2 h {w}^{2}$$

$${κ}_{F} = \frac{{C}_{F + S} - {C}_{S}}{{d}_{F}}$$

Differential Scanning Calorimetry of Monomers

Differential scanning calorimetry of dialdehyde monomers B2, B3 and B4 was performed using a Perkin Elmer DSC 8500 instrument. Samples were heated and cooled at 10° C./min from −52° C. to 258° C. in two cycles. Significant transition temperatures from the second cycle are set out in Table 2.

Results set out in Table 2 show higher crystallinity for alkoxy-substituted monomers B2 and B3 as compared to alkyl-substituted monomer B2.

TABLE 2

| | Melting | Crystallisation |
|---|---|---|
| | temperature/ | temperature/ |
| Monomer | ° C. | ° C. |
| B2 | 75 | None |
| B3 | 117 | 75 |
| B4 | 134 | 101 |

Effect of Polymerisation Method

The effects of film formation methods on thermal conductivities was investigated. Polymers were made from monomer A3 with either monomer B2 or B3 as described above by in-situ solution polymerisation or in-situ melt polymerisation.

The in-situ solution polymerisation was performed as described above.

For in-situ melt polymerisation, an equimolar ratio of monomers A3 and B3 were weighed into a mortar and a small amount of a non-solvent liquid added to act as grinding agent, and the mixture was ground into a paste using a pestle. Additional liquid was added in order to form a dispersion at a concentration of 20 mg/ml. After mixing the ink is promptly dropcast onto the substrate already described for thermal conductivity measurement.

A gasket prepared from 0.5 mm thick fluorosilicone rubber sheet (Silex Silicones Ltd) and applied to the substrate is used to contain the ink within a prescribed area (18×10 mm rectangle) for the dropcasting procedure. The wet film is dried by evaporation on a hotplate set at a low temperature so as not to cause dissolution or reaction of the dispersed solids, for example 40° C. The substrate was then removed from the hotplate and transferred to a second hotplate preheated to 140° C. It can be observed that the monomers first melt to a liquid state, and then a polymeric film is formed returning the sample to a solid state. After this has taken place (within 5 minutes) the substrate is moved to a cooling station and the silicone gasket removed.

Thermal conductivities were measured using the method described above.

| | Thermal Conductivity (WmK⁻¹) | |
|---|---|---|
| | | In-situ-melt |
| Monomer | In-situ-solution | processing |
| B2 | 0.32 | — |
| B3 | 0.5 | 0.28 |

1. A polymer comprising a repeating structure of formula (I): 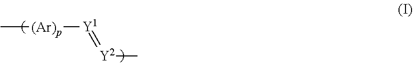
wherein Ar in each occurrence is an arylene or heteroarylene group; p is at least 2; one of Y¹ and Y² is CR¹ wherein R¹ is H or a substituent; and the other of Y¹ and Y² is N.

2. The polymer according to claim 1 wherein p is 2-5.

3. The polymer according to claim 1 wherein each Ar of (Ar)p is independently selected from para-phenylene, thiophene, furan, and benzobisoxazole, each of which may independently be unsubstituted or substituted with one or more substituents.

4. The polymer according to claim 1 wherein each Ar of (Ar)p is the same.

5. The polymer according to claim 1 wherein one or more Ar groups of (Ar)ₚ are substituted with one or more substituents selected from substituents R² wherein R² in each occurrence is independently selected from:
F;
CN;
NO₂;
branched, linear or cyclic C₁₋₂₀ alkyl wherein one or more non-adjacent C-atoms may be replaced with O, S, NR⁵, SiR⁶₂, C═O or COO wherein R⁵ in each occurrence is H or a substituent and R⁶ in each occurrence is independently a substituent; or
an aryl or heteroaryl group Ar⁵ which is unsubstituted or substituted with one or more substituents.

6. The polymer according to claim 5 wherein at least one R² is a C₁₋₂₀ alkyl or C₁₋₁₉ alkoxy group.

7. The polymer according to claim 1 wherein R¹ is H or a C₁₋₂₀ hydrocarbyl group.

8. The polymer according to claim 1 wherein a divalent linker group L disposed in the polymer backbone, wherein L is selected from O, S, NR⁵ or a C₁₋₁₂ alkylene group wherein one or more non-adjacent C atoms of a C₂₋₁₂ alkylene group may be replaced with O, S, NR⁵, SiR⁶₂, CO or COO wherein R⁵ in each occurrence is H or a substituent and R⁶ in each occurrence is independently a substituent.

9. The polymer according to claim 1 wherein the repeating structure of formula (I) is comprised in a repeating group of formula (II), (III) or (IV). 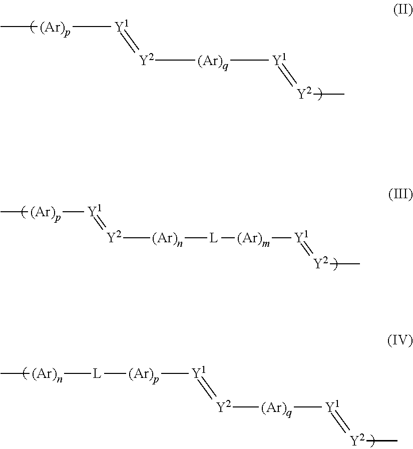
wherein:
q is at least 1;
n is 0 or a positive integer;
m is 0 or a positive integer; and
L is selected from O, S, NR⁵ or a C₁₋₁₂ alkylene group wherein one or more non-adjacent C atoms of a C₂₋₁₂ alkylene group may be replaced with O, S, NR⁵, SiR⁶₂, CO or COO wherein R⁵ in each occurrence is H or a substituent and R⁶ in each occurrence is independently a substituent.

10. A film comprising a polymer according to claim 1.

11. A method of forming a film according to claim 10 comprising deposition of one or more monomers for forming the polymer onto a surface and polymerising the one or more monomers.

12. (canceled)

13. The method according to claim 11 wherein the surface is a surface of a functional layer of an electronic device.

14. An apparatus comprising a heat-generating device, a heat transfer device configured to transfer heat away from the heat-generating device and a film according to claim 10 disposed between the heat-generating device and the heat transfer device.

15. An electronic device comprising a film according to claim 10 disposed on a functional layer thereof.

16. The electronic device according to claim 15 wherein the film is disposed in a region between the surface of the functional layer and a first surface of a first chip electrically connected to the functional layer.

17. The electronic device according to claim 16 wherein the functional layer is a printed circuit board; an interposer; or a second chip.

18. (canceled)

19. A heat sink comprising a first surface having fins extending therefrom and an opposing second surface having a film according to claim 10 disposed thereon.

20. A method of forming a polymer according to claim 1 comprising polymerisation of a monomer or monomers having reactive groups which react to form Y¹═Y².

21. The method according to claim 20 comprising polymerisation of a first monomer selected from formulae (M1-A) and (M1-B) and a second monomer selected from formulae (M2-A) and (M2-B):
X¹—(Ar)ₚ—X¹ (M1-A)
X¹—(Ar)ₚ-L-(Ar)ₙ—X¹ (M1-B)
X²—(Ar)_{q}—X² (M2-A)
X²—(Ar)ₙ-L-(Ar)ₘ—X² (M2-B)
wherein one of X¹ and X² is a group of formula —C(═O)R¹ and the other of X¹ and X² is NH₂; q is at least 1; n is 0 or a positive integer; and m is 0 or a positive integer; and L is selected from O, S, NR⁵ or a C₁₋₁₂ alkylene group wherein one or more non-adjacent C atoms of a C₂₋₁₂ alkylene group may be replaced with O, S, NR⁵, SiR⁶₂, CO or COO wherein R⁵ in each occurrence is H or a substituent and R⁶ in each occurrence is independently a substituent.

22. (canceled)

23. A formulation comprising one or more monomers for forming the polymer according to claim 1 and a liquid.

24. (canceled)
